(19) United States
(12) Patent Application Publication
(10) Pub. No.: US 2026/0107494 A1
(43) Pub. Date: Apr. 16, 2026

(54) HETEROJUNCTION FIELD EFFECT TRANSISTOR AND MANUFACTURING METHOD THEREOF

(71) Applicant: ChipsK Corp., Gyeonggi-do (KR)

(72) Inventors: Gokhan ATMACA, Seoul (KR); Min Gi Jeong, Gyeonggi-do (KR); Chol Ho Kwak, Gyeonggi-do (KR); Ho Young Cha, Seoul (KR)

(21) Appl. No.: 19/345,543

(22) Filed: Sep. 30, 2025

(30) Foreign Application Priority Data
Oct. 11, 2024 (KR) 10-2024-0138879

(51) Int. Cl. H10D 30/47; H01L 23/29; H01L 23/31; H10D 30/01; H10D 62/10; H10D 62/824; H10D 64/27

(52) U.S. Cl. CPC H10D 30/475; H10D 30/015; H10D 62/102; H10D 62/824; H10D 64/411; H10W 74/137; H10W 74/43

(57) ABSTRACT

Disclosed herein are a heterojunction field effect transistor that can improve operation characteristics by forming a dual insulator layer between a p-GaN layer and a gate electrode and a manufacturing method thereof. The disclosed heterojunction field effect transistor includes: a substrate; a buffer layer formed on the substrate; a channel layer formed on the buffer layer and including a two-dimensional electron channel; a source electrode and a drain electrode formed on the channel layer and spaced apart from each other; a barrier layer formed between the source electrode and the drain electrode and inducing a formation of the two-dimensional electron channel at an interface with the channel layer; a p-GaN layer formed on the barrier layer; a double insulator layer formed on the p-GaN layer and made of different materials; and a gate electrode formed on the double insulator layer.

### CROSS-REFERENCE TO RELATED APPLICATION

This application claims priority from and the benefit of Korean Patent Application No. 10-2024-0138879, filed on 11 Oct. 2024, the disclosures of which are incorporated herein by reference in their entirety.

### FIELD

The present disclosure relates to a heterojunction field effect transistor, and more particularly, to a heterojunction field effect transistor that can improve operation characteristics by forming a dual insulator layer between a p-GaN layer and a gate electrode and a manufacturing method thereof.

On the other hand, the present invention was supported by the national research and development program as follows.

| | |
|---|---|
| Project identification number | 1415184162 |
| Detailed project number | 00144490 |
| Department name | Ministry of Trade, Industry and Energy |
| Name of project management | Korea Planning & Evaluation Institute of Industrial |
| organization | Technology |
| Research program name | Compound-Material-Based Next-Generation |
| | Power Semiconductor Technology Development Project |
| Title of research project | Development of a high-efficiency, intelligent solar |
| | energy conversion system integrated with 600 V- |
| | class GaN devices |
| Contribution rate | 100% |
| Name of organization carrying | ChipsK Corp. |
| out the project | |
| Research period | 2022 Apr. 1~2025 Mar. 31 |

| | |
|---|---|
| Project identification number | 2410000115 |
| Detailed project number | RS-2022-00143570 |
| Department name | Ministry of Trade, Industry and Energy |
| Name of project management | Korea Planning & Evaluation Institute of Industrial |
| organization | Technology |
| Research program name | Development of core epitaxial and device |
| | technologies for 2 kV vertical GaN power devices |
| Title of research project | Development of a high-efficiency, intelligent solar |
| | energy conversion system integrated with 600 V- |
| | class GaN devices. |
| Contribution rate | 100% |
| Name of organization carrying | ChipsK Corp. |
| out the project | |
| Research period | 2022 Apr. 1~2025 Dec. 31 |

### BACKGROUND

Gallium nitride (GaN) is a material with a wide energy bandgap, has advantages such as high switching characteristics, high breakdown voltage, and high electron mobility, and is being actively researched to overcome the material limitations of silicon (Si) generally used for an existing semiconductor and to be applied to power semiconductor fields.

In particular, the heterojunction structure of AlGaN and GaN causes spontaneous polarization and piezoelectric polarization due to differences in crystal structures, lattice constants, etc., resulting in the formation of a two-dimensional electron channel (2DEG) where electrons are accumulated between AlGaN and GaN. The two-dimensional electron channel has the advantage of high electron density and electron mobility without special doping.

FIG. 1A illustrates a heterojunction field effect transistor with normally-on characteristics. Referring to FIG. 1A, a heterojunction field effect transistor 10a according to the related art includes a substrate 1, a buffer layer 2, a channel layer 3, a barrier layer 4, a source electrode S, a drain electrode D, and a gate electrode G. The channel layer 3 can be formed of GaN, the barrier layer 4 can be formed of AlGaN, and a two-dimensional electron channel (2DEG) is formed at an interface between the channel layer 3 and the barrier layer 4. Due to the two-dimensional electron channel (2DEG), the field effect transistor having the AlGaN/GaN heterojunction structure has normally-on characteristics. However, since the two-dimensional electron channel causes the AlGaN/GaN heterojunction device to have normally-on characteristics, it is important to manufacture the AlGaN/GaN heterojunction device in a normally-off manner.

Representative heterojunction field effect transistors implemented to have normally-off operation characteristics include a heterojunction field effect transistor 10b having a recessed MIS gate structure in which AlGaN under the gate is etched as illustrated in FIG. 1B, or a heterojunction field effect transistor 10c having a p-GaN gate structure in which a p-GaN layer 5 is used under the gate metal as illustrated in FIG. 1C.

Recently, as illustrated in FIG. 1D, the heterojunction field effect transistor is evolving into a p-GaN gate MOS or MIS-HEMT in which an insulator layer 6 is inserted between the gate electrode G and the p-GaN layer 5.

The heterojunction field effect transistor 10d in FIG. 1D can achieve wider gate swing and improved gate forward breakdown voltage by adjusting a depletion region at a high electric field of Schottky contact/p-GaN interface.

However, such a design shows a significant improvement in gate forward breakdown, but has a problem in that hole injection is limited due to the insertion of the insulator between the Schottky contact and the p-GaN layer. Korean Patent Application Publication No. 10-2019-0112526

### SUMMARY

### Technical Problem

The present disclosure has been made in view of the technical background as described above, and is directed to a heterojunction field effect transistor that can improve operation characteristics by forming a dual insulator layer between a p-GaN layer and a gate electrode and a manufacturing method thereof.

### Technical Solution

A heterojunction field effect transistor according to an embodiment of the present disclosure includes: a substrate; a buffer layer formed on the substrate; a channel layer formed on the buffer layer and including a two-dimensional electron channel; a source electrode and a drain electrode formed on the channel layer and spaced apart from each other; a barrier layer formed between the source electrode and the drain electrode and inducing a formation of the two-dimensional electron channel at an interface with the channel layer; a p-GaN layer formed on the barrier layer; a double insulator layer formed on the p-GaN layer and made of different materials; and a gate electrode formed on the double insulator layer.

In the heterojunction field effect transistor according to an embodiment of the present disclosure, the double insulator layer may include a first insulator layer made of SiO₂ and a second insulator layer formed on the first insulator layer and made of Al₂O₃.

In the heterojunction field effect transistor according to an embodiment of the present disclosure, the double insulator layer may include a p-GaN double insulator layer formed at both ends of the p-GaN layer and a p-GaN second insulator layer formed inside the p-GaN double insulator layer.

In the heterojunction field effect transistor according to an embodiment of the present disclosure, an ohmic contact region, where the gate electrode is in contact with the p-GaN layer, may be formed inside the p-GaN second insulator layer.

A manufacturing method of a heterojunction field effect transistor according to an embodiment of the present disclosure includes: sequentially forming a substrate, a buffer layer, a channel layer, a barrier layer, and a p-GaN layer; stacking a first insulator layer on an entire surface of the p-GaN layer, and etching a part of the first insulator layer to expose a part of the p-GaN layer; stacking a second insulator layer made of a material different from a material of the first insulator layer on an entire surface of the first insulator layer, and etching a part of the second insulator layer to expose a part of the p-GaN layer, thereby forming a dual insulator layer on the p-GaN layer; and stacking a gate electrode material on an entire surface of the dual insulator layer, and etching the gate electrode material to form a gate electrode.

In the manufacturing method of a heterojunction field effect transistor according to an embodiment of the present disclosure, the double insulator layer may include a first insulator layer made of SiO₂ and a second insulator layer formed on the first insulator layer and made of Al₂O₃.

In the manufacturing method of a heterojunction field effect transistor according to an embodiment of the present disclosure, the double insulator layer may include a p-GaN double insulator layer formed at both ends of the p-GaN layer and a p-GaN second insulator layer formed inside the p-GaN double insulator layer.

In the manufacturing method of a heterojunction field effect transistor according to an embodiment of the present disclosure, an ohmic contact region, where the gate electrode is in contact with the p-GaN layer, may be formed inside the p-GaN second insulator layer.

### Advantageous Effects

According to an embodiment of the present disclosure, operation characteristics can be improved by forming a dual insulator layer between a p-GaN layer and a gate electrode. Various other effects according to an embodiment of the present disclosure are included in the following detailed description.

### BRIEF DESCRIPTION OF DRAWINGS

FIGS. 1A, 1B, 1C and 1D are cross-sectional views illustrating a heterojunction field effect transistor according to the related art.

FIG. 2A is a cross-sectional view illustrating a heterojunction field effect transistor according to an embodiment of the present disclosure.

FIG. 2B is an enlarged cross-sectional view of a circled portion in FIG. 2A.

FIGS. 3A, 3B, 3C, 3D and 3E are cross-sectional views illustrating a manufacturing method of a heterojunction field effect transistor according to an embodiment of the present disclosure.

FIGS. 4A and 4B are cross-sectional views illustrating a heterojunction field effect transistor of a comparative example.

FIG. 5A is a graph showing the amount of a drain current with respect to a gate voltage.

FIG. 5B is a graph showing the amount of a leakage current with respect to a gate voltage.

FIG. 6 is a graph showing conduction band bending.

FIG. 7A is a graph showing the amount of a gate leakage current with respect to a gate voltage.

FIG. 7B is a graph showing the magnitude of an electric field with respect to a horizontal distance.

FIGS. 8A and 8B are graphs showing the amount of a drain current with respect to a drain voltage.

FIG. 9A is a graph showing the amount of a breakdown current with respect to a breakdown voltage.

FIG. 9B is a graph showing the magnitude of an electric field with respect to a horizontal distance.

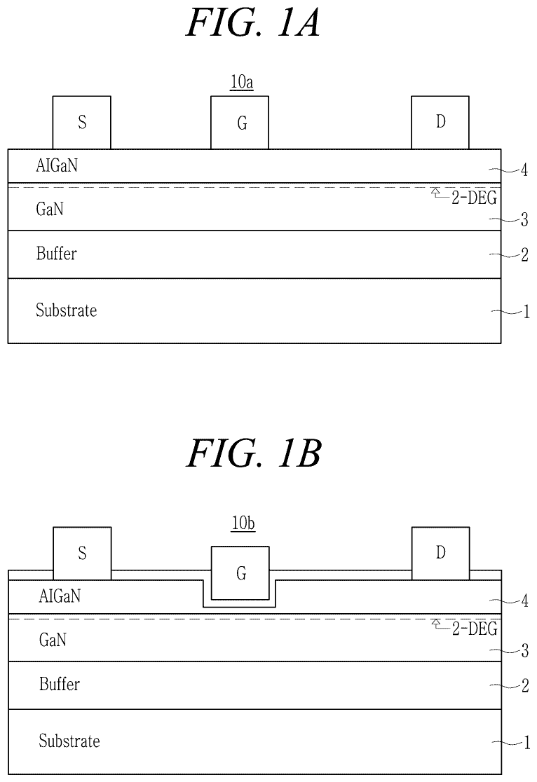

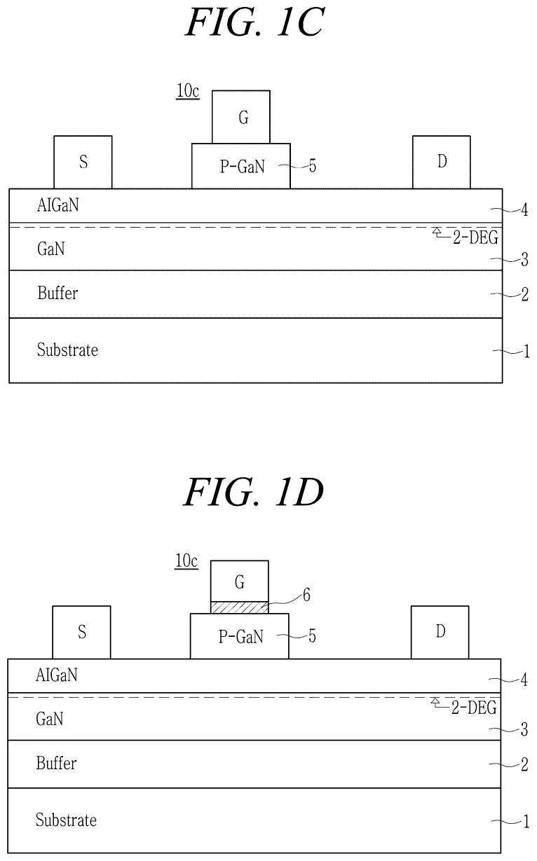

### LIST OF REFERENCE NUMERALS

110: Substrate
120: Buffer layer
130: Channel layer
140: Barrier layer
150: p-GaN layer
160: Dual insulator layer
S: Source electrode
D: Drain electrode
G: Gate electrode

### DETAILED DESCRIPTION

The aforementioned purposes, features, and advantages are described in detail below with reference to the accompanying drawings, thereby allowing those skilled in the art to which the present disclosure pertains to easily carry out the technical idea of the present disclosure. In describing the present disclosure, a detailed description of known technologies related to the present disclosure will be omitted if it is deemed to unnecessarily obscure the subject matter of the present disclosure. Preferred embodiments according to the present disclosure are described in detail below with reference to the accompanying drawings. In the drawings, the same reference numerals are used to indicate identical or similar components.

Although terms such as first and second are used to describe various components, it is of course that these components are not limited by these terms. These terms are merely used to distinguish one component from another component, and unless otherwise specified, it is of course that a first component may also be a second component.

In the following, the arrangement of any configuration “above (or below)” of a component or “on (or under)” a component may mean not only that any configuration is placed in contact with an upper surface (or lower surface) of the component, but also that another configuration may be interposed between the component and any configuration placed on (or under) the component.

In addition, when a component is described as being “connected,” “joined,” or “coupled” to another component, it should be understood that the components may be directly connected or coupled to each other, but that another component may also be “interposed” between the components, or that each component may be “connected,” “joined,” or “coupled” through another component.

Throughout the specification, unless otherwise specified, each component may be singular or plural.

As used herein, an expression in a singular form includes an expression in a plural form unless the context clearly indicates otherwise. In this application, terms such as “comprises” or “includes” should not be construed as necessarily including all components or steps described in the specification, and should be construed as not including some of the components or steps or as including additional components or steps.

Throughout the specification, “A and/or B” indicates A, B, or A and B unless otherwise specified, and “C to D” indicates C or more and D or less unless otherwise specified.

A heterojunction field effect transistor and a manufacturing method thereof according to an embodiment of the present disclosure are described below with reference to the drawings.

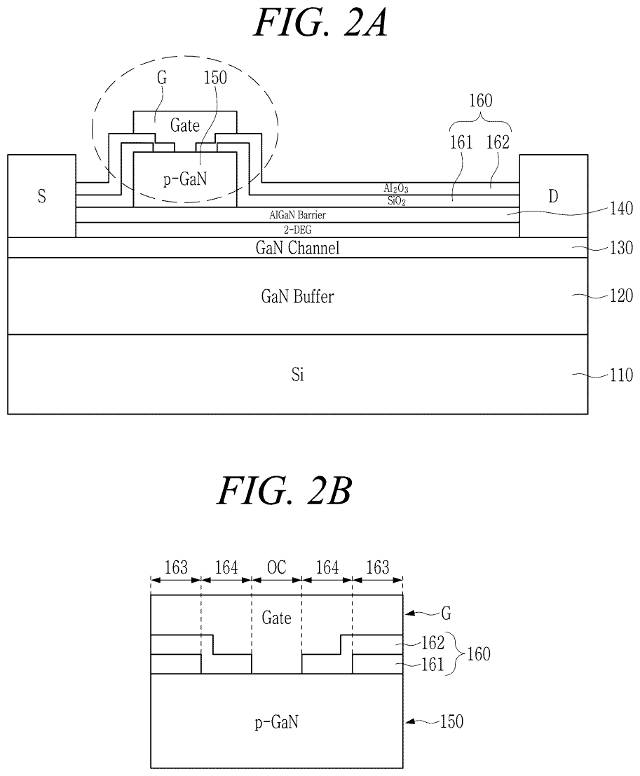

FIG. 2A is a cross-sectional view illustrating a heterojunction field effect transistor according to an embodiment of the present disclosure, and FIG. 2B is an enlarged cross-sectional view of a circled portion in FIG. 2A.

Referring to FIGS. 2A and 2B, the heterojunction field effect transistor according to an embodiment of the present disclosure includes a substrate 110, a buffer layer 120, a channel layer 130, a barrier layer 140, a p-GaN layer 150, a double insulator layer 160, a source electrode S, a drain electrode D, and a gate electrode G.

The substrate 110 may be a growth substrate such as a sapphire substrate, an AlN substrate, a GaN substrate, a SiC substrate, or a Si substrate, and is not particularly limited as long as it is a substrate capable of growing a semiconductor.

The buffer layer 120 may serve as a nucleus layer that facilitates the growth of the channel layer 130, and serve to mitigate a lattice constant mismatch between the substrate 110 and the channel layer 130. Preferably, the buffer layer 120 may be a GaN buffer layer made of GaN. The buffer layer 120 may be preferably formed to have a thickness of 3.5 μm.

The channel layer 130 is formed on the buffer layer 120 and is formed of a first nitride semiconductor having a first energy bandgap. The first nitride semiconductor is not particularly limited and may be, for example, a binary nitride semiconductor such as undoped GaN or InN, a ternary nitride semiconductor such as AlGaN or InGaN, or a quaternary nitride semiconductor such as AlInGaN. In addition, the channel layer 130 may be doped with an n-type impurity (donor) or a p-type impurity (acceptor). Preferably, the channel layer 130 may be a GaN channel layer made of GaN. The channel layer 130 may be preferably formed to have a thickness of 100 nm.

The source electrode S and the drain electrode D are formed on the channel layer 130 and spaced apart from each other.

The barrier layer 140 is formed on the channel layer 130 between the source electrode S and the drain electrode D, and induces the formation of a two-dimensional electron channel (2DEG) at an interface with the channel layer 130. The barrier layer 140 is formed of a second nitride semiconductor having a second energy bandgap. The second energy bandgap indicates an energy bandgap different from the first energy bandgap. The second nitride semiconductor is not particularly limited and may be, for example, a binary nitride semiconductor such as undoped GaN or InN, a ternary nitride semiconductor such as AlGaN or InGaN, or a quaternary nitride semiconductor such as AlInGaN. In addition, the barrier layer 140 may be doped with an n-type or p-type impurity. In addition, the second nitride semiconductor may be a material having a larger energy bandgap than the first nitride semiconductor forming the channel layer 130. Preferably, the barrier layer 140 may be an AlGaN barrier layer made of AlGaN.

The barrier layer 140 may be formed to have a thickness of 10 nm to 20 nm, preferably 15 nm. When the barrier layer 140 is formed to have a thickness of less than 10 nm, a polarization phenomenon may not be performed well, making it difficult to sufficiently form a two-dimensional electron channel. When the barrier layer 140 is formed to have a thickness exceeding 20 nm, the excessive formation of a two-dimensional electron channel under the gate may lead to a normally-on operation. A two-dimensional electron channel (2DEG) is formed at the interface between the channel layer 130 and the barrier layer 140.

This specification describes an example in which the channel layer 130 is a GaN channel layer made of GaN and the barrier layer 140 is an AlGaN barrier layer made of AlGaN; however, the present disclosure is not necessarily limited thereto.

In addition, the p-GaN layer 150 and the gate electrode G are formed on the barrier layer 140, and the double insulator layer 160 made of different materials is formed between the p-GaN layer 150 and the gate electrode G.

The double insulator layer 160 includes a first insulator layer 161 and a second insulator layer 162 formed on the first insulator layer 161. The double insulator layer 160 is formed on the barrier layer 140 and the p-GaN layer 150. The first insulator layer 161 may be made of SiO₂, and the second insulator layer 162 may be made of Al₂O₃.

The double insulator layer 160 formed on the p-GaN layer 150 is formed to extend inward from both ends of the p-GaN layer 150 by a predetermined length and then terminated, and the second insulator layer 162 is formed to extend inward again from the terminated position by a predetermined length and then terminated. This results in the formation of an ohmic contact region OC where the p-GaN layer 150 and the gate electrode G are in direct contact with each other. Through the ohmic contact region OC, hole injection can be performed from the gate electrode G to the AlGaN/GaN heterojunction structure.

That is, the double insulator layer 160 is not completely stacked on the p-GaN layer 150, but the double insulator layer 160 is stacked only at both ends of the p-GaN layer 150. Subsequently, the second insulator layer 162 is formed inside the double insulator layer 160, and the gate electrode G is formed inside the second insulator layer 162 to be in contact with the p-GaN layer 150, so that the ohmic contact region OC is formed.

In the following description, the double insulator layer 160 formed at both ends of the p-GaN layer 150 is referred to as a “p-GaN double insulator layer 163”, and the second insulator layer 162 formed inside the p-GaN double insulator layer 163 is referred to as a “p-GaN second insulator layer 164”. In the following description, a “width” refers to a region in contact with the p-GaN layer 150.

The first insulator layer 161 and the second insulator layer 162 are preferably formed to have a thickness of 3 nm to 20 nm, respectively. The second insulator layer 162 is formed in direct contact with the first insulator layer 161 and the p-GaN layer 150. When the thickness of each of the first insulator layer 161 and the second insulator layer 162 is less than 3 nm, it is too thin to expect an effect of an electric field dispersion. When the thickness of each of the first insulator layer 161 and the second insulator layer 162 exceeds 20 nm, an electric field is dispersed, resulting in a loss of gate controllability.

When the first and second insulator layers 161 and 162 are each formed to have a thickness of less than 3 nm, there is no reduction in an electric field. However, when they are formed to have a thickness exceeding 20 nm, there is a problem in that an electric field is reduced.

The p-GaN second insulator layer 164 is preferably formed to have a width of 0.1 μm to 1.0 μm. When the width of the p-GaN second insulator layer 164 is less than 0.1 μm, process implementation is difficult. When the width of the p-GaN second insulator layer 164 exceeds 1 μm, the size (width) of an active region including the gate electrode G increases, resulting in deterioration of device characteristics.

The p-GaN double insulator layer 163 is preferably formed to have a width of 0.1 μm to 1.0 μm. When the width of the p-GaN double insulator layer 163 is less than 0.1 μm, process implementation is difficult. When the width of the p-GaN double insulator layer 163 exceeds 1 μm, the size (width) of an active region including the gate electrode G increases, resulting in deterioration of device characteristics.

The ohmic contact region OC is preferably formed to a width of 0.1 μm to 2.0 μm. When the width of the ohmic contact region OC is less than 0.1 μm, process implementation is difficult. When the width of the ohmic contact region OC exceeds 2 μm, the size (width) of an active region including the gate electrode G increases, resulting in deterioration of device characteristics.

For example, the first insulator layer 161 may be 5 nm-thick SiO₂, the second insulator layer 162 may be 5 nm-thick Al₂O₃, the p-GaN double insulator layer 163 may be 10 nm-thick and 0.25 μm-wide SiO₂/Al₂O₃, the p-GaN second insulator layer 164 may be 5 nm-thick and 0.25 μm-wide Al₂O₃, and the ohmic contact region OC may be formed to have a width of 0.5 μm. The p-GaN layer 150 and the gate electrode G may each be formed to have a width of 1.5 μm.

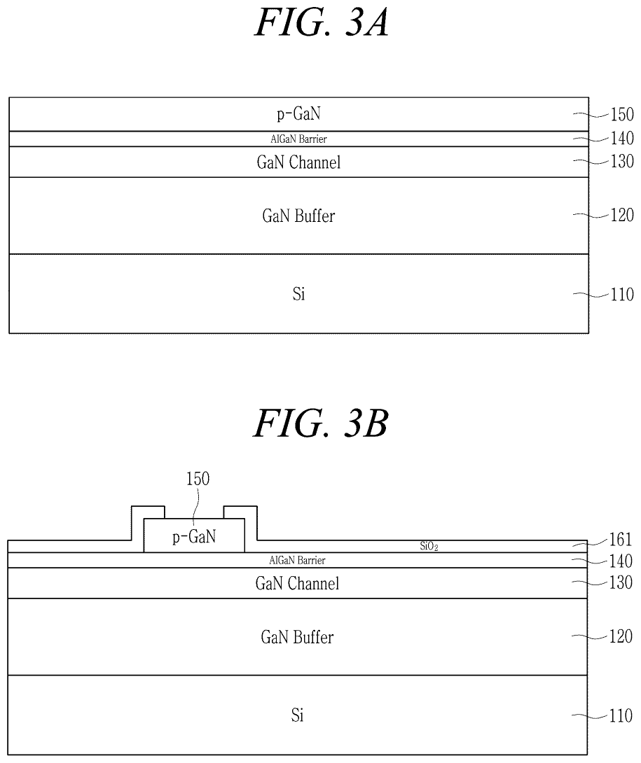

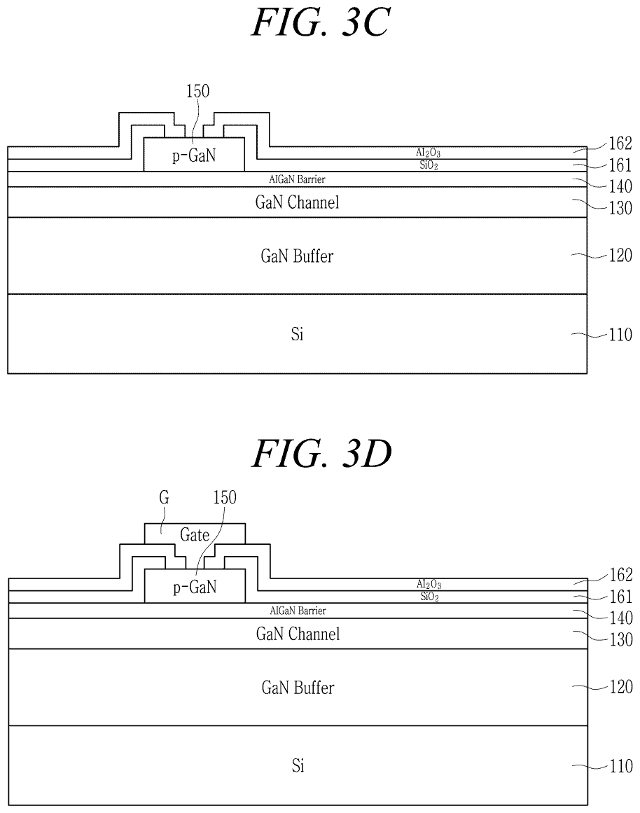

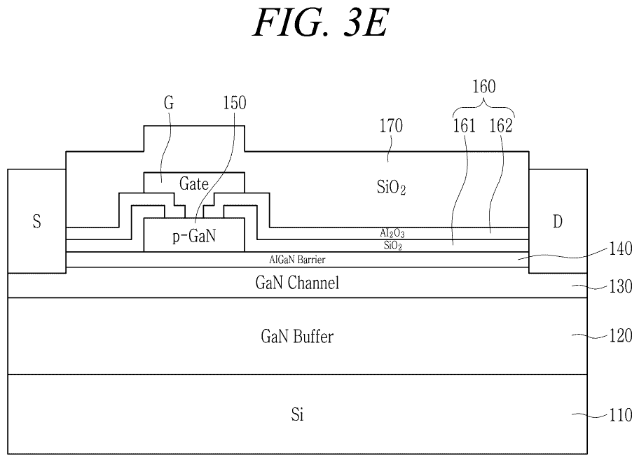

A manufacturing method of the heterojunction field effect transistor according to an embodiment of the present disclosure is described below with reference to FIGS. 3A to 3E. FIGS. 3A to 3E are cross-sectional views illustrating the manufacturing method of the heterojunction field effect transistor according to an embodiment of the present disclosure.

First, as illustrated in FIG. 3A, the substrate 110, the buffer layer 120, the channel layer 130, the barrier layer 140, and the p-GaN layer 150 are sequentially stacked.

Subsequently, as illustrated in FIG. 3B, the p-GaN layer 150 is etched, the first insulator layer 161 is stacked on an entire surface of the p-GaN layer 150, and then a part of the first insulator layer 161 formed on the etched p-GaN layer 150 is etched to expose a part of the p-GaN layer 150. The first insulator layer 161 may be made of SiO₂.

Subsequently, as illustrated in FIG. 3C, the second insulator layer 162 is stacked over an entire surface of the first insulator layer 161, and then a part of the second insulator layer 162 on the p-GaN layer 150 is etched to expose a part of the p-GaN layer 150. The second insulator layer 162 may be made of Al₂O₃.

Subsequently, as illustrated in FIG. 3D, a gate electrode material is stacked on an entire surface of the second insulator layer 162, and is then etched to form the gate electrode G. As a result, the p-GaN double insulator layer 163 is formed at both ends of the p-GaN layer 150, the p-GaN second insulator layer 164 is formed inside the p-GaN double insulator layer 163, and the ohmic contact region OC is formed inside the p-GaN second insulator layer 164.

Subsequently, as illustrated in FIG. 3E, an insulating layer 170 is stacked on the entire surface of the second insulator layer 162, and layers at locations where the source electrode S and the drain electrode D are to be formed are etched, and then the source electrode S and the drain electrode D are formed.

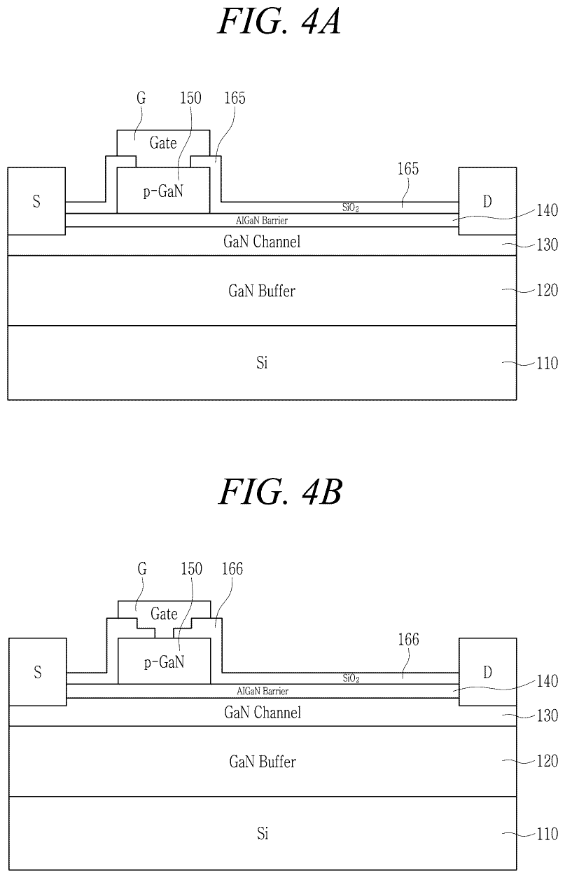

The improvement of the characteristics of the heterojunction field effect transistor according to an embodiment of the present disclosure is described below with reference to FIGS. 4A, 4B, 5A, 5B, 6, 7A, 7B, 8A, 8B, 9A, and 9B.

FIGS. 4A and 4B are cross-sectional views illustrating a heterojunction field effect transistor of a comparative example.

FIG. 4A illustrates a heterojunction field effect transistor in which a single insulator layer 165 made of SiO₂ is formed to have a thickness of 5 nm between the p-GaN layer 150 and the gate electrode G and an ohmic contact region is formed in which the p-GaN layer 150 and the gate electrode G are in direct contact with each other, and the heterojunction field effect transistor has the same configuration as the heterojunction field effect transistor of the present disclosure except that the double insulator layer 160 is composed of the single insulator layer 165.

FIG. 4B illustrates a heterojunction field effect transistor in which two layers of a double insulator layer 166 made of SiO₂ are formed to have thicknesses of 10 nm and 5 nm between the p-GaN layer 150 and the gate electrode G and an ohmic contact region is formed in which the p-GaN layer 150 and the gate electrode G are in direct contact with each other, and the heterojunction field effect transistor has the same configuration as the heterojunction field effect transistor of the present disclosure except that the two layers of the double insulator layer 166 are made of the same material.

The first comparative example and the second comparative example do not mean the related art.

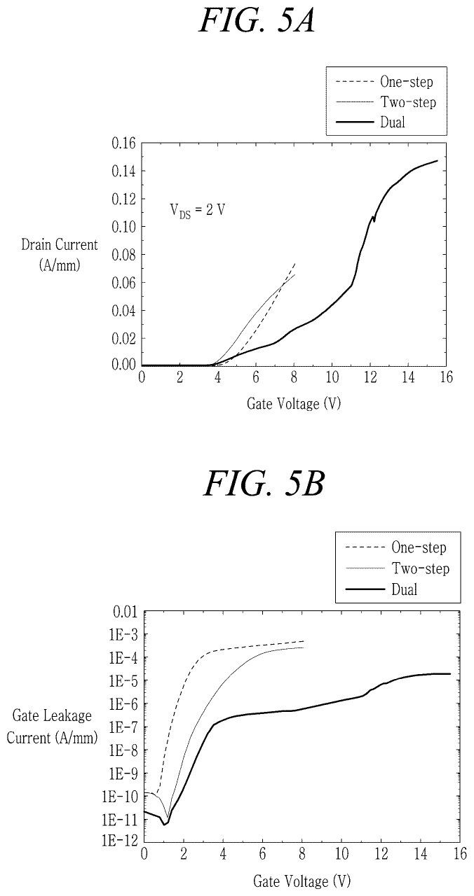

In the following description, the first comparative example illustrated in FIG. 4A is referred to as “One-Step”, the second comparative example illustrated in FIG. 4B is referred to as “Two-Step”, and the present disclosure is referred to as “Dual”. Likewise, in FIGS. 5A, 5B, 6, 7A, 7B, 8A, 8B, 9A, and 9B, the first comparative example is referred to as “One-Step”, the second comparative example is referred to as “Two-Step”, and the present disclosure is referred to as “Dual”. Graphs in FIGS. 5A, 5B, 6, 7A, 7B, 8A, 8B, 9A, and 9B are graphs obtained using values acquired by simulating the present disclosure, the first comparative example, and the second comparative example.

FIG. 5A is a graph showing the amount of a drain current with respect to a gate voltage, and FIG. 5B is a graph showing the amount of a leakage current with respect to a gate voltage.

Referring to FIG. 5A, it can be confirmed that the first comparative example One-Step and the second comparative example Two-Step show no response at a gate voltage above 8 V because a gate leakage current reaches a limit, but the present disclosure Dual was found to show a drain current response while maintaining a low gate leakage current even at a gate voltage of approximately 15 V, indicating that the present disclosure Dual shows a greater gate swing.

Referring to FIGS. 5A and 5B, it can be confirmed that the present disclosure Dual shows a greater gate swing than the comparative examples and a lower leakage current at a high gate voltage.

It can be confirmed that the first comparative example One-Step shows a high drain current at a gate voltage of 8 V, but shows the gate leakage current already exceeding 1×10⁻⁴ A/mm at a gate voltage of 3 V and the second comparative example Two-Step shows a gate leakage current of 1×10⁻⁴ A/mm at a gate voltage of 7 V.

On the other hand, it can be confirmed that the present disclosure Dual shows a gate leakage current that does not reach 1×10⁻⁴ A/mm even when the gate voltage reaches 15 V. This demonstrates that using the double insulator layer of SiO₂ and Al₂O₃ is effective in suppressing a gate leakage current even at a high gate voltage of 10 V or higher.

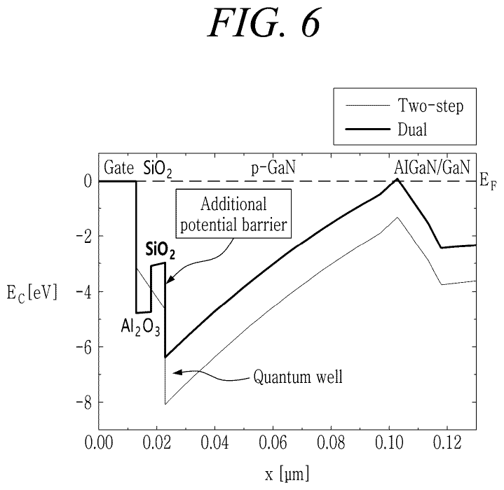

FIG. 6 is a graph showing conduction band bending.

Referring to FIG. 6, it can be confirmed that compared to the second comparative example Two-Step, the SiO₂/Al₂O₃ double insulator layer of the present disclosure Dual adjusts conduction band bending between the gate electrode and the p-GaN layer. It can be confirmed that the Al₂O₃/SiO₂ interface of the double insulator layer generates an additional potential barrier between electrons located at the interface between the gate electrode and the AlGaN/GaN due to difference in permittivity thereof, and the additional potential barrier serves to suppress a high gate leakage current level.

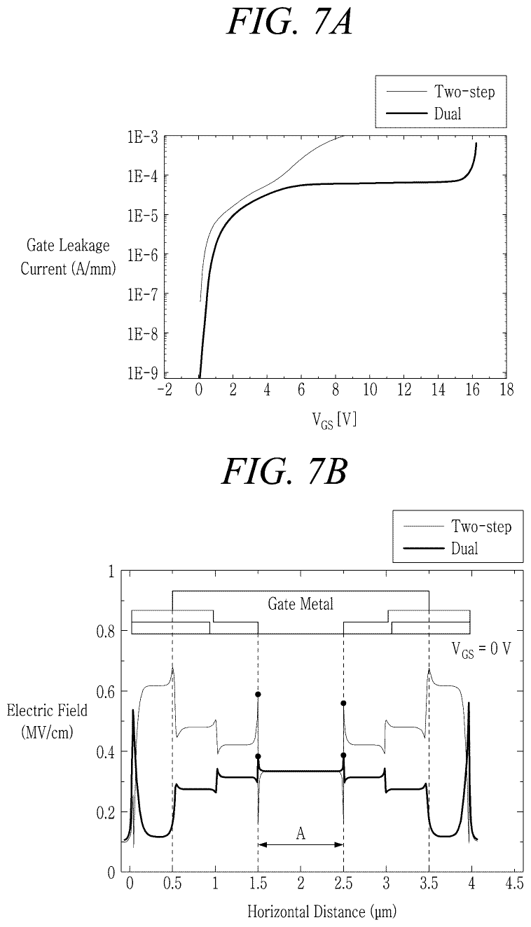

FIG. 7A is a graph showing the amount of a gate leakage current with respect to a gate voltage, and FIG. 7B is a graph showing the magnitude of an electric field with respect to a horizontal distance. FIGS. 7A and 7B show a state in which a bias is applied to the gate electrode (gate ON state).

Referring to FIG. 7A, it can be confirmed that the present disclosure Dual shows a higher gate forward breakdown voltage (16.3 V) than the second comparative example Two-Step. This indicates that the present disclosure Dual shows a larger gate swing.

In FIG. 7B, the horizontal distance of 0.5 indicates the left end of the p-GaN layer 150, and the horizontal distance of 3.5 indicates the right end of the p-GaN layer 150. The horizontal distance of 1.5 to 2.5 indicates an interface region A between the gate electrode and the p-GaN layer, and the electric field has a simulated value at a point 1 nm away from the bottom of the gate electrode.

Referring to FIG. 7B, it can be confirmed that the present disclosure Dual shows a lower electric field than the second comparative example Two-Step not only in the interface region A between the gate electrode and the p-GaN layer, but also in all regions. This indicates that the present disclosure Dual shows a lower breakdown voltage.

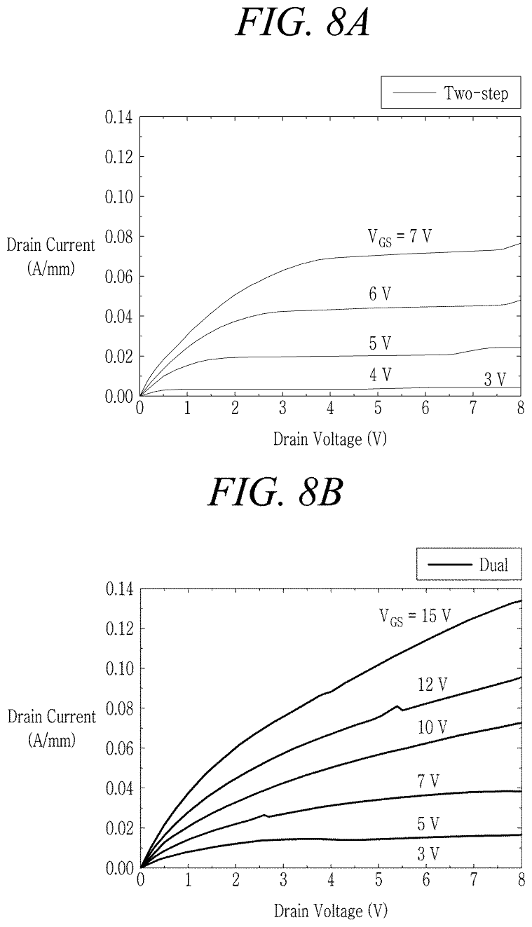

FIGS. 8A and 8B are graphs showing the amount of a drain current with respect to a drain voltage.

Referring to FIG. 8A, it can be confirmed that the drain voltage of the second comparative example Two-Step appears only up to 7 V. Referring to FIG. 8B, it can be confirmed that the drain voltage of the present disclosure Dual appears up to 15 V. It can be confirmed from the above that the present disclosure Dual shows a wider gate voltage operating range.

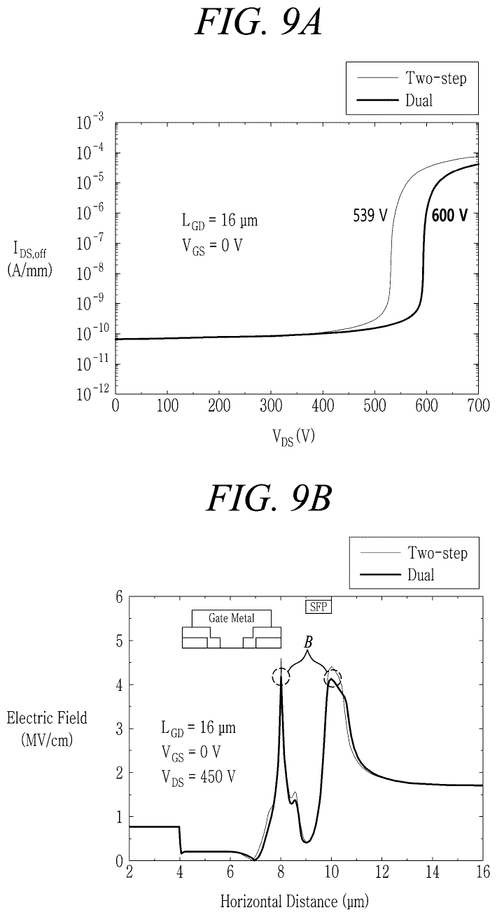

FIG. 9A is a graph showing the amount of a breakdown current with respect to a breakdown voltage, and FIG. 9B is a graph showing the magnitude of an electric field with respect to a horizontal distance. FIGS. 9A and 9B show a state in which a bias is applied to the source/drain electrode (gate OFF state).

Referring to FIG. 9A, it can be confirmed that the present disclosure Dual shows a higher breakdown voltage (about 600 V) than the second comparative example Two-Step.

Referring to FIG. 9B, it can be confirmed that since the present disclosure Dual uses the dual insulator layer of SiO₂/Al₂O₃, conduction band energy under the gate electrode is adjusted due to the high permittivity of Al₂O₃ and thus a peak electric field under a drain edge of the p-GaN layer is reduced along the channel (see B).

While the embodiments of the present disclosure have been described above, those skilled in the art will appreciate that various modifications and variations of the present disclosure can be made by adding, modifying, deleting, or adding components without departing from the spirit of the present disclosure as set forth in the claims. Such modifications and variations also fall within the scope of the present disclosure.

What is claimed is:

1. A heterojunction field effect transistor comprising:
a substrate;
a buffer layer formed on the substrate;
a channel layer formed on the buffer layer and including a two-dimensional electron channel;
a source electrode and a drain electrode formed on the channel layer and spaced apart from each other;
a barrier layer formed between the source electrode and the drain electrode and inducing a formation of the two-dimensional electron channel at an interface with the channel layer;
a p-GaN layer formed on the barrier layer;
a double insulator layer formed on the p-GaN layer and made of different materials; and
a gate electrode formed on the double insulator layer.

2. The heterojunction field effect transistor according to claim 1, wherein the double insulator layer includes a first insulator layer made of SiO₂ and a second insulator layer formed on the first insulator layer and made of Al₂O₃.

3. The heterojunction field effect transistor according to claim 2 wherein the double insulator layer includes a p-GaN double insulator layer formed at both ends of the p-GaN layer and a p-GaN second insulator layer formed inside the p-GaN double insulator layer.

4. The heterojunction field effect transistor according to claim 3 wherein an ohmic contact region, where the gate electrode is in contact with the p-GaN layer, is formed inside the p-GaN second insulator layer.

5. A manufacturing method of a heterojunction field effect transistor, the manufacturing method comprising:
sequentially forming a substrate, a buffer layer, a channel layer, a barrier layer, and a p-GaN layer;
stacking a first insulator layer on an entire surface of the p-GaN layer, and etching a part of the first insulator layer to expose a part of the p-GaN layer;
stacking a second insulator layer made of a material different from a material of the first insulator layer on an entire surface of the first insulator layer, and etching a part of the second insulator layer to expose a part of the p-GaN layer, thereby forming a dual insulator layer on the p-GaN layer; and
stacking a gate electrode material on an entire surface of the dual insulator layer, and etching the gate electrode material to form a gate electrode.

6. The manufacturing method according to claim 5 wherein the double insulator layer includes the first insulator layer made of SiO₂ and the second insulator layer formed on the first insulator layer and made of Al₂O₃.

7. The manufacturing method according to claim 6 wherein the double insulator layer includes a p-GaN double insulator layer formed at both ends of the p-GaN layer and a p-GaN second insulator layer formed inside the p-GaN double insulator layer.

8. The manufacturing method according to claim 7 wherein an ohmic contact region, where the gate electrode is in contact with the p-GaN layer, is formed inside the p-GaN second insulator layer.
